(19) United States
(12) Patent Application Publication
(10) Pub. No.: US 2013/0037074 A1
(43) Pub. Date: Feb. 14, 2013

(54) THIN FILM SOLAR CELL STRING

(71) Applicants: Jeffrey S. Britt, Tucson, AZ (US); Eric Kanto, Tucson, AZ (US); Charles D. Gambill, II, Tucson, AZ (US)

(72) Inventors: Jeffrey S. Britt, Tucson, AZ (US); Eric Kanto, Tucson, AZ (US); Charles D. Gambill, II, Tucson, AZ (US)

(73) Assignee: GLOBAL SOLAR ENERGY, INC., Tucson, AZ (US)

(21) Appl. No.: 13/482,699

(22) Filed: May 29, 2012

Related U.S. Application Data
(63) Continuation of application No. 12/364,440, filed on Feb. 2, 2009, now abandoned.
(60) Provisional application No. 61/063,257, filed on Jan. 31, 2008.
(60) Provisional application No. 61/109,828, filed on Oct. 30, 2008.

(51) Int. Cl. H01L 31/05; H01L 31/18

(52) U.S. Cl. 136/244; 438/67; 257/E31.11

(57) ABSTRACT

Thin film PV cells and strings of such cells that may be electrically joined with conductive tabs or ribbons. A semi-flexible, electrically conductive adhesive is applied to join the tabs to the front and back of a cell, providing a conductive pathway between the tab and solar cell, with good adhesion to both. The tabs may be constructed of one or more materials having a thermal expansion coefficient that closely matches that of the substrate material of the cells, so that when the string or module is subsequently heated, mechanical stress between the tab and solar cell is minimized. The semi-flexible nature of the ECA also acts to relieve stress between the tab and the solar cell, decreasing the possibility of adhesion failure at critical locations. One or more dielectric materials may be applied to the PV cells and/or the tabs in regions where a tab crosses the edge of a cell, to avoid electrical shorting between the negative and positive electrodes of the cell.

### CROSS-REFERENCE TO RELATED APPLICATION

This is a continuation application of U.S. patent application Ser. No. 12/364,440 filed Feb. 2, 2009 which claims priority under 35 U.S.C. §119 and applicable foreign and international law of U.S. Provisional Patent Application Ser. Nos. 61/063,257 filed Jan. 31, 2008 and 61/109,828 filed Oct. 30, 2008, all of which are hereby incorporated by reference in their entireties.

### BACKGROUND

The field of photovoltaics generally relates to multi-layer materials that convert sunlight directly into DC electrical power. The basic mechanism for this conversion is the photovoltaic (or photoelectric) effect, first correctly described by Einstein in a seminal 1905 scientific paper for which he was awarded a. Nobel Prize for physics. In the United States, photovoltaic (PV) devices are popularly known as solar cells. Solar cells are typically configured as a cooperating sandwich of p-type and n-type semiconductors, in which the n-type semiconductor material (on one “side” of the sandwich) exhibits an excess of electrons, and the p-type semiconductor material (on the other “side” of the sandwich) exhibits an excess of holes, each of which signifies the absence of an electron. Near the p-n junction between the two materials, valence electrons from the n-type layer move into neighboring holes in the p-type layer, creating a small electrical imbalance inside the solar cell. This results in an electric field in the vicinity of the junction.

When an incident photon excites an electron in the cell into the conduction band, the excited electron becomes unbound from the atoms of the semiconductor, creating a free electron/hole pair. Because, as described above, the p-n junction creates an electric field in the vicinity of the junction, electron/hole pairs created in this manner near the junction tend to separate and move away from junction, with the electron moving toward the n-type side, and the hole moving toward the p-type side of the junction. This creates an overall charge imbalance in the cell, so that if an external conductive path is provided between the two sides of the cell, electrons will move from the n-type side back to the p-type side along the external path, creating an electric current. In practice, electrons may be collected from at or near the surface of the n-type side by a conducting grid that covers a portion of the surface, while still allowing sufficient access into the cell by incident photons.

Such a photovoltaic structure, when appropriately located electrical contacts are included and the cell (or a series of cells) is incorporated into a closed electrical circuit, forms a working PV device. As a standalone device, a single conventional solar cell is not sufficient to power most applications. As a result, solar cells are commonly arranged into PV modules, or “strings,” by connecting the front of one cell to the back of another, thereby adding the voltages of the individual cells together in electrical series. Typically, a significant number of cells are connected in series to achieve a usable voltage. The resulting DC current then may be fed through an inverter, where it is transformed into AC current at an appropriate frequency, which is chosen to match the frequency of AC current supplied by a conventional power grid. In the United States, this frequency is 60 Hertz (Hz), and most other countries provide AC power at either 50 Hz or 60 Hz.

One particular type of solar cell that has been developed for commercial use is a “thin film” PV cell. In comparison to other types of PV cells, such as crystalline silicon PV cells, thin film PV cells require less light-absorbing material to create a working cell, and thus can reduce processing costs. Thin film based PV cells also offer improved cost by employing previously developed deposition techniques widely used in the thin film industries for protective, decorative, and functional coatings. Common examples of low cost commercial thin film products include water permeable coatings on polymer-based food packaging, decorative coatings on architectural glass, low emissivity thermal control coatings on residential and commercial glass, and scratch and anti-reflective coatings on eyewear. Adopting or modifying techniques that have been developed in these other fields has allowed a reduction in development costs for PV cell thin film deposition techniques.

Furthermore, thin film cells, particularly those employing a sunlight absorber layer of copper indium diselenide, copper indium disulfide, copper indium aluminum diselenide, or copper indium gallium diselenide, have exhibited efficiencies approaching 20%, which rivals or exceeds the efficiencies of the most efficient crystalline cells. In particular, copper indium gallium diselenide (CIGS) is stable, has low toxicity, and is truly thin film, requiring a thickness of less than two microns in a working PV cell. As a result, to date CIGS appears to have demonstrated the greatest potential for high performance, low cost thin film PV products, and thus for penetrating bulk power generation markets.

Thin film PV materials may be deposited either on rigid glass substrates, or on flexible substrates. Glass substrates are relatively inexpensive, generally have a coefficient of thermal expansion that is a relatively close match with the CIGS or other absorber layers, and allow for the use of vacuum deposition systems. However, such rigid substrates suffer from various shortcomings, such as a need for substantial floor space for processing equipment and material storage, specialized heavy duty handling equipment, a high potential for substrate fracture, increased shipping costs due to the weight and delicacy of the glass, and difficulties in installation. As a result, the use of glass substrates does not readily lend itself to large-volume, high-yield, commercial manufacturing of multi-layer functional thin film materials such as photovoltaics.

In contrast, roll-to-roll processing of thin flexible substrates allows for the use of compact, less expensive vacuum systems, and of non-specialized equipment that already has been developed for other thin film industries. PV cells based on thin flexible substrate materials also exhibit a relatively high tolerance to rapid heating and cooling and to large thermal gradients (resulting in a low likelihood of fracture or failure during processing), require comparatively low shipping costs, and exhibit a greater ease of installation than cells based on rigid substrates. Additional details relating to the composition and manufacture of thin film PV cells of a type suitable for use with the presently disclosed methods and apparatus may be found, for example, in U.S. Pat. Nos. 6,310,281, 6,372,538, and 7,194,197, all to Wendt et al. These patents are hereby incorporated into the present disclosure by reference for all purposes.

As noted previously, a significant number of PV cells often are connected in series to achieve a usable voltage, and thus a desired power output. Such a configuration is often called a module or “string” of PV cells. Due to the different properties of crystalline substrates and flexible thin film substrates, the electrical series connection between cells may be constructed differently for a thin film cell than for a crystalline cell, and forming reliable series connections between thin film cells poses several challenges. For example, soldering (the traditional technique used to connect crystalline solar cells) directly on thin film cells exposes the PV coatings of the cells to damaging temperatures, and the organic-based silver inks typically used to form a collection grid on thin film cells may not allow strong adherence by ordinary solder materials in any case. Thus, PV cells often are joined with wires or conductive tabs attached to the cells by methods other than soldering.

However, even when wires or tabs are used to form inter-cell connections, the extremely thin coatings and potential flaking along cut PV cell edges introduces opportunities for shorting (power loss) wherever a wire or tab crosses over a cell edge. Furthermore, the conductive substrate on which the PV coatings are deposited, which typically is a metal foil, may be easily deformed by thermo-mechanical stress from attached wires and tabs. This stress can be transferred to weakly-adhering interfaces, which can result in delamination of the cells. In addition, adhesion between the wires or tabs and the cell back side, or between the wires or tabs and the conductive grid on the front side, can be weak, and mechanical stress may cause separation of the wires or tabs at these locations. Also, corrosion can occur between the molybdenum or other coating on the back side of a cell and the material that joins the tab to the solar cell there. This corrosion may result in a high-resistance contact or adhesion failure, leading to power losses.

As a result of the problems described above, there is a need for an improved string of interconnected thin film PV cells that overcomes some or all of the shortcomings of existing thin film PV modules.

### SUMMARY

The present teachings disclose thin film PV cells and strings of such cells that may be electrically joined with conductive tabs or ribbons. A semi-flexible, electrically conductive adhesive (ECA) is applied to join the tabs to the front and back of a cell, providing a conductive pathway between the tab and solar cell, with good adhesion to both. The tabs may be constructed of one or more materials having a thermal expansion coefficient that closely matches that of the substrate material of the cells, so that when the string or module is subsequently heated, mechanical stress between the tab and solar cell is minimized. The semi-flexible nature of the ECA also acts to relieve stress between the tab and the solar cell, decreasing the possibility of adhesion failure at critical locations. One or more dielectric materials may be applied to the PV cells and/or the tabs in regions where a tab crosses the edge of a cell, to avoid electrical shorting between the negative and positive electrodes of the cell.

### BRIEF DESCRIPTION OF THE DRAWINGS

FIG. 1 is a top elevational view of a thin film photovoltaic cell, in accordance with aspects of the present disclosure.

FIG. 2 is a top view showing a magnified edge portion of the photovoltaic cell of FIG. 1.

FIG. 3 is a side elevational view showing a magnified edge portion of the photovoltaic cell of FIG. 1.

FIG. 4 is a side elevational view showing additional details of the edge portion shown in FIG. 3 under further magnification.

FIG. 5 is a perspective view of the photovoltaic cell of FIG. 1.

FIG. 6 is a perspective view showing a magnified edge portion of the photovoltaic cell of FIG. 5.

FIG. 7 is a perspective view showing two thin film photovoltaic cells coupled together by conductive tabs.

FIG. 8 is a bottom elevational view of the coupled photovoltaic cells of FIG. 7.

FIG. 9 is a perspective view of a magnified portion of the coupled photovoltaic cells of FIG. 7, showing details of adjacent edge portions of the coupled cells.

FIG. 10 is a magnified perspective view showing another pair of thin film photovoltaic cells coupled together by conductive tabs according to aspects of the present teachings.

FIG. 11 is a magnified perspective view showing still another pair of thin film photovoltaic cells coupled together by conductive tabs according to aspects of the present teachings.

FIG. 12 is a magnified perspective view yet showing another pair of thin film photovoltaic cells coupled together by conductive tabs according to aspects of the present teachings.

FIG. 13 is a flowchart depicting methods of manufacturing strings or modules of photovoltaic cells according to aspects of the present teachings.

### DETAILED DESCRIPTION

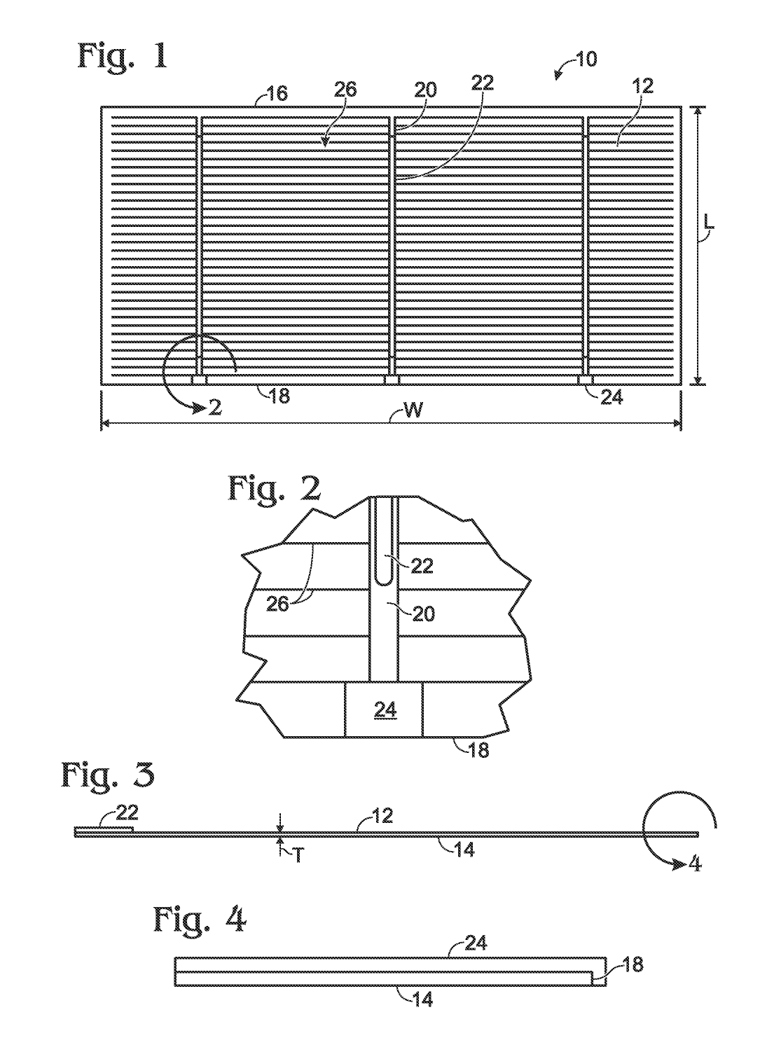

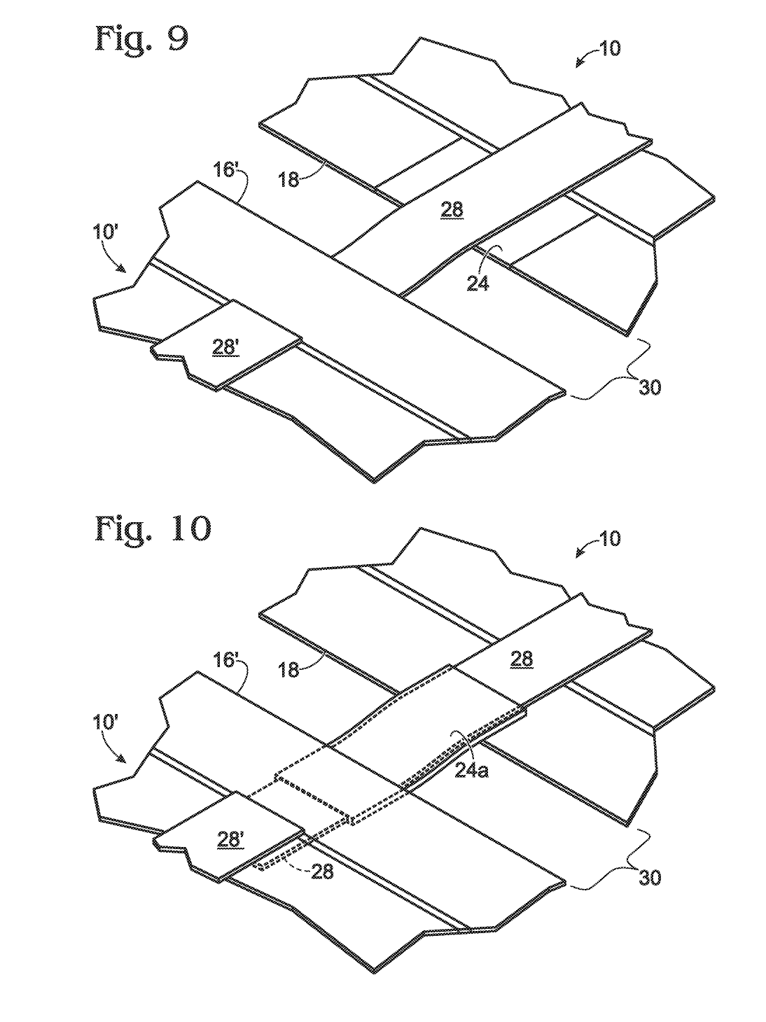

FIG. 1 shows a top view of a thin film photovoltaic cell 10, in accordance with aspects of the present disclosure. Cell 10 is substantially planar, and typically rectangular as depicted in FIG. 1, although shapes other than rectangular may be more suitable for specific applications, such as for an odd-shaped rooftop or other surface. The cell has a top surface 12, a bottom surface 14 (see, e.g., FIG. 3 and FIG. 8), and dimensions including a length L, a width W, and a thickness T. The length and width may be chosen for convenient application of the cells and/or for convenience during processing, and typically are in the range of a few centimeters (cm) to tens of cm. For example, the length may be approximately 100 millimeters (mm), and the width may be approximately 210 mm, although any other suitable dimensions may be chosen. For reasons that will be described below, the edges spanning the width of the cell may be characterized respectively as a leading edge 16 and a trailing edge 18. The total thickness of cell 10 depends on the particular layers chosen for the cell, and is typically dominated by the thickness of the underlying substrate of the cell. For example, a stainless steel substrate may have thickness on the order of 0.025 mm, whereas all of the other layers of the cell may have a combined thickness on the order of 0.01 mm or less.

Cell 10 is created by starting with a flexible substrate, and then sequentially depositing multiple thin layers of different materials onto the substrate. This assembly may be accomplished through a roll-to-roll process whereby the substrate travels from a pay-out roll to a take-up roll, traveling through a series of deposition regions between the two rolls. The PV material then may be cut to cells of any desired size. The substrate material in a roll-to-roll process is generally thin, flexible, and can tolerate a relatively high-temperature environment. Suitable materials include, for example, a high temperature polymer such as polyimide, or a thin metal such as stainless steel or titanium, among others. Sequential layers typically are deposited onto the substrate in individual processing chambers by various processes such as sputtering, evaporation, vacuum deposition, and/or printing. These layers may include a molybdenum (Mo) or chromium/molybdenum (Cr/Mo) back contact layer; an absorber layer of material such as copper indium diselenide, copper indium disulfide, copper indium aluminum diselenide, or copper indium gallium diselenide (CIGS); a buffer layer such as a layer of cadmium sulfide (CdS), which may prevent the diffusion of impurities into the absorber layer; and an antireflective transparent conducting oxide (TCO) layer. In addition, a conductive current collection grid, typically constructed from silver (Ag) or some other conductive metal, is typically applied over the TCO layer.

Although the precise thickness of each layer of a thin-film PV cell depends on the exact choice of materials and on the particular application process chosen for forming each layer, exemplary materials, thicknesses and methods of application of each layer described above are as follows, proceeding in typical order of application of each layer onto the substrate:

| Layer | Exemplary | Exemplary | Exemplary Method |
|---|---|---|---|
| Description | Material | Thickness | of Application |
| Substrate | Stainless steel | 25 μm | N/A (stock material) |
| Back contact | Mo | 320 nm | Sputtering |
| Absorber | CIGS | 1700 nm | Evaporation |
| Buffer | CdS | 80 nm | Chemical deposition |
| Front electrode | TCO | 250 nm | Sputtering |
| Collection grid | Ag | 40 μm | Printing |

Further details regarding these layers, including possible alternative layering materials, layer thicknesses, and suitable application processes for each layer are described, for example, in U.S. Pat. No. 7,194,197.

According to aspects of the present disclosure, a plurality of cells may be joined together in electrical series using electrically conductive tabs. The function and construction of these tabs will be described in detail below. To facilitate this interconnection of cells, one or more additional materials may be deposited on top of the TCO layer and/or the conductive grid of each cell. For example, as depicted in FIG. 2, which is a magnified view of a portion of cell 10 adjacent to its leading edge 18, a conductive layer in the form of one or more relatively narrow conductive strips 20 may be deposited, either in conjunction with the collection grid, or as a separate layer. These strips may be constructed from any suitable conductive material, including metals such as copper, tin, silver, or an appropriate alloy, and may extend across most or all of length L of the cell. The width of each strip 20 may be chosen according to the overall scale of the cell. For a cell of dimensions 100 mm×210 mm, the width of each strip is typically in the range of 1.0-2.0 mm, and a width of approximately 1.5 mm has been found suitable.

A bead 22 of electrically conductive adhesive (ECA) may be disposed on each of strips 20 (or directly on the TCO/grid layers, if strips 20 are omitted). Alternatively, as described in more detail below, the ECA beads may be deposited on the conductive tabs to be attached to the cells, rather than on the cells themselves. In either case, each ECA bead 22 generally is substantially linear, and slightly narrower than the associated conductive strip. For example, for a strip of width 1.5 mm, each bead may be approximately 1.3 mm wide, leaving approximately 0.1 mm between each side of the bead and the edge of the associated conductive strip. Each bead extends along a central portion of the length of each conductive strip 20, which may be 60% or more of the length of the cell. For example, for a cell of length 100 mm, each bead may be 60-80 mm long, leaving approximately 10-15 mm between each end of the bead and the respective leading and trailing edges of the cell. As shown in FIG. 3, beads 22 are applied in a thin layer, with a thickness generally somewhat comparable to the thickness of cell 10 in the absence of the beads. For example, adhesive beads 22 each may have a thickness of approximately 0.1 mm-0.5 mm.

The ECA used in beads 22 generally will be semi-flexible, and also may be chosen to have various other advantageous properties. For example, the chosen ECA may be curable at a temperature less than 225 degrees Celsius (° C.), or in some cases less than 200° C., to avoid possible heat damage to other components of the cell. The ECA also may contain a corrosion inhibiting agent, to decrease the likelihood of corrosion during environmental exposure. ECAs suitable with the methods and apparatus described in this disclosure include, for example, a metallic/polymeric paste, an intrinsically conductive polymer, or any other suitable semi-flexible, electrically conductive adhesive material. In some cases, an epoxy resin, such as a bisphenol-A or bisphenol-B based resin, may be combined with a conductive filler such as silver, gold, or palladium to form an ECA. Alternative resins include urethanes, silicones, and various other thermosetting resins, and alternative conductive fillers include nickel, copper, carbon, and other metals, as well as metal coated fibers, spheres, glass, ceramics, or the like. Suitable corrosion inhibitors include heterocyclic or cyclic compounds and various silanes. Specific examples of compounds that may be appropriate include salicylaldehyde, glycidoxypropyltrimethoxysilane, 8-hydroxyquinoline, and various compounds similar to 8-hydroxyquinoline, among others.

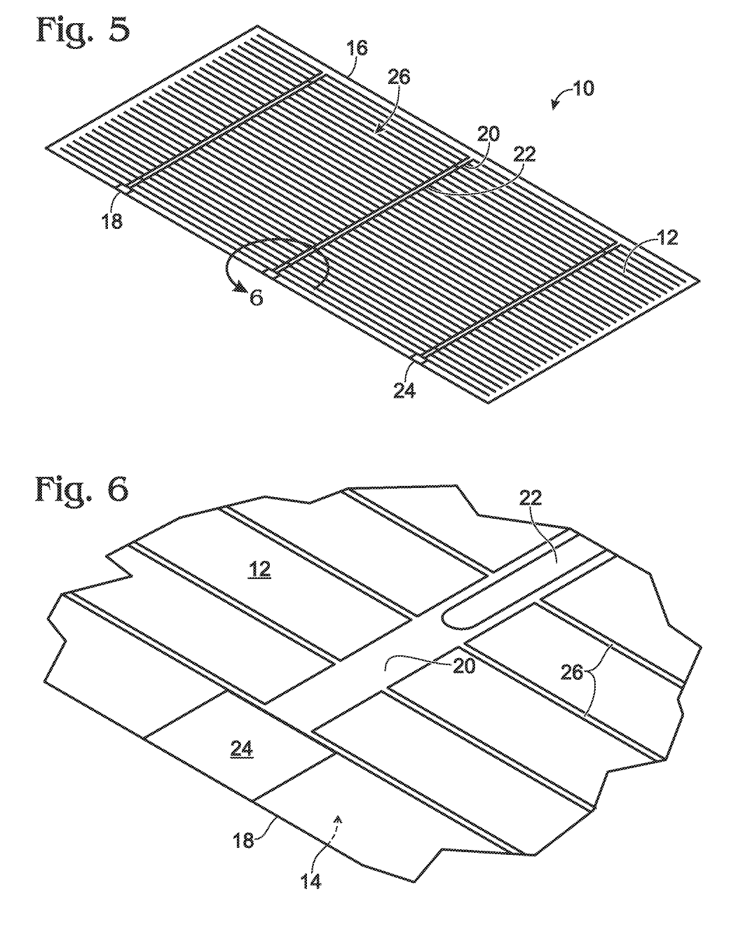

One or more dielectric patches 24 also may be applied adjacent to the trailing edge of the cell and either overlapping or adjacent to the associated conductive strip (if any), in approximate linear alignment with each conductive strip 20 and each associated ECA bead 22. As shown in FIG. 2, patches 24 typically will be somewhat wider than both strips 20 and beads 22. For instance, for a conductive strip of width 1.5 mm, the dielectric patch may be approximately 5.0 mm wide and approximately 3.4 mm long. For reasons described below, dielectric patches 24 are configured to provide a nonconductive barrier at the trailing edge of the cell. To accomplish this, as depicted in FIG. 4, each patch 24 may be deposited over the trailing edge of the cell to overlap substantially the entire thickness of the cell. The thickness of each patch 24 is generally in the range of 0.01 mm-0.1 mm. Patches 24 may be constructed from any appropriate dielectric material, such as an oxide- or fluoride-based material, a flexible acrylic UV thermosetting polymer, UV curable silicone, epoxy and urethane formulations, two-part formulations of a catalyst and a resin such as epoxy, acrylic, or urethane, and air-drying or air-cured silicones and urethanes, among others. Dielectric patches may be applied using printing, sputtering or any other suitable application technique.

FIGS. 5-6, respectively, show perspective views of cell 10, and of a magnified region of cell 10 near trailing edge 18. FIG. 6 is magnified to a greater extent than FIG. 2, and shows that conductive strips 20 may be adjacent to or contiguous with a conductive collection grid 26 that appears as a plurality of horizontal lines in FIGS. 1-2. Grid 26 is configured to collect and guide electrons that are dislodged by incoming photons from the CIGS (or similar) absorber layer of the cell, in a manifestation of the photovoltaic effect. Thus, grid 26 may be constructed from the same or a similar conductive material as strips 20, and if constructed from the same material, the grid may be applied to the cell in the same processing operation as strips 20. For example, both the grid and the strips may be a conductive silver ink layer, applied to the cell by printing and having a thickness of approximately 0.04 mm.

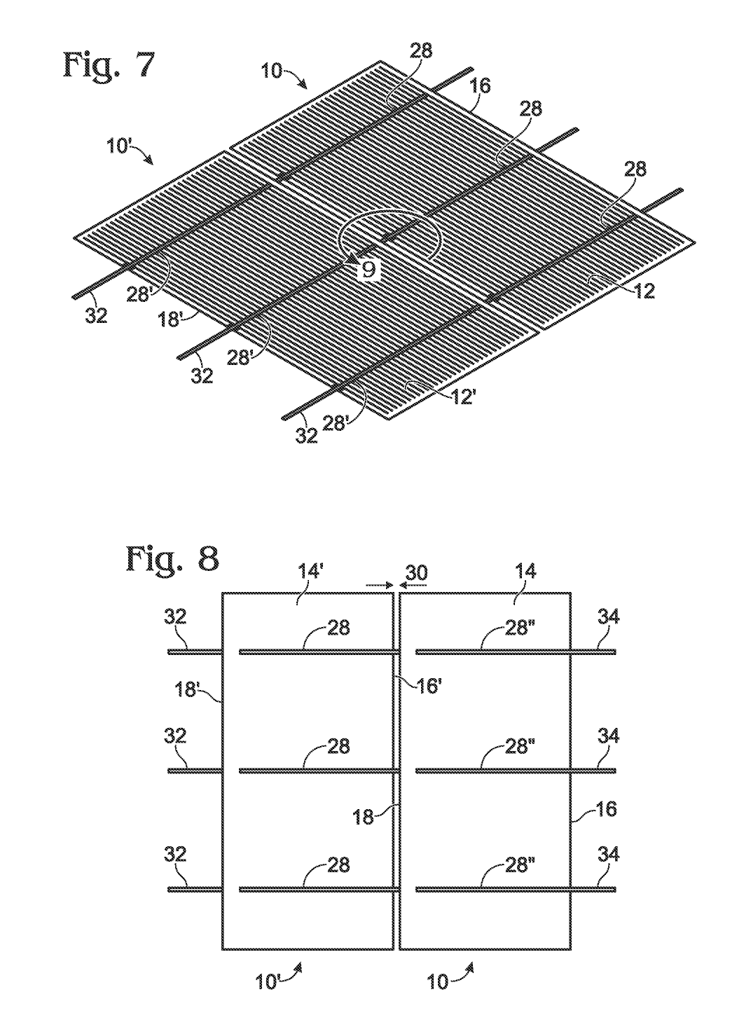

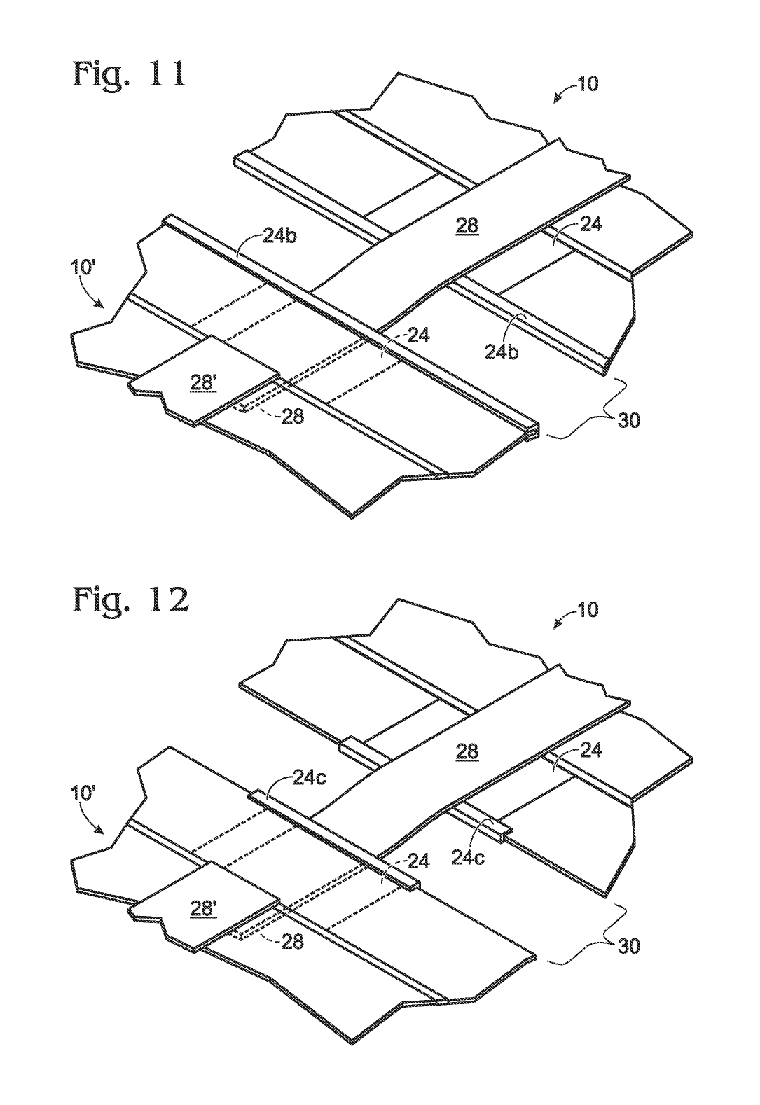

FIGS. 7-9 show two PV cells 10, 10′ of the type generally described above, connected in an electrical series (or string) by three electrically conductive tabs 28. FIG. 7 is a perspective view of the top of the interconnected cells, FIG. 8 is a bottom view, and FIG. 9 is a magnified top perspective view of a region of the interconnected cells near where the cells are adjacent to each other. Cell 10′ is constructed in similar fashion to cell 10, and the cells typically will have a common width, length, and thickness. Primed reference numbers (e.g., 12′, 14′, etc.) will be used to designate portions of cell 10′ corresponding to similar portions of cell 10 designated by the same, unprimed reference numbers. Although exactly two cells are depicted in FIGS. 7-9, the methods and apparatus disclosed herein are more generally applicable to connecting any number of PV cells, and may be used to construct a string or 2-dimensional array of any number of cells, depending on the desired voltage or power output for a particular PV cell application. For instance, a plurality of cells can be interconnected to form modules capable of producing 6, 12, 30, 60, or 120 Watts of power.

Conductive tabs 28 are substantially linear, and are adhered to the top surface of cell 10 by adhesive beads 22. This securely attaches the tabs to the cell, and also establishes electrical contact between each tab and the top surface of cell 10. As an alternative to applying the adhesive beads to the surface of the cell, each bead may be applied to an underside of the corresponding tab. In other words, the adhesive serves substantially the same purpose so long as it is disposed between the tab and a surface of the cell, regardless of whether a bead is initially applied to the cell or to the tab. As depicted in FIGS. 7-8, each tab 28 may extend along the length of the cell to make contact with the entirety of the associated adhesive bead, and may extend slightly further, to a point within a few millimeters of the leading edge of cell 10. Because, as described previously, beads 22 typically extend along 60%-80% of the length of the top surface of cell 10, this results in a relatively long region of both electrical contact and adhesion between the tabs and the top surface of the cell.

As is best seen in FIG. 9, to connect cells 10 and 10′, each tab 28 extends toward the trailing edge 18 of cell 10, over the associated dielectric patch 24, past the trailing edge, and under the adjacent cell 10′. As FIG. 9 illustrates, cells 10 and 10′ (and in general, any two adjacent cells) may be nonoverlapping, and a gap 30 may separate the adjacent cells to allow tabs 28 to bend or otherwise be deformed slightly in the boundary region between the cells. Gap 30 may have any suitable length to allow sufficient deformation of each tab, although because each gap represents an area that is not used to expose a PV cell to solar energy, a minimal gap is desirable from a space efficiency standpoint. For cells of length 100 mm and width 210 mm, a gap of approximately 3 mm has been found sufficient. The presence of the dielectric patch, including its possible overlap of the entire thickness of cell 10, prevents electrical shorting that could occur through electrical contact between tabs 28 and the oppositely charged (i.e., positive) electrode of cell 10.

As depicted in FIG. 8, which shows the bottom surfaces of cells 10 and 10′, upon crossing the boundary region between the two cells, each tab 28 may extend along a substantial fraction of the bottom surface of cell 10′, to within a few millimeters (or any other desired distance) from trailing edge 18′ of cell 10′. Adhesive beads 22′ may be disposed either linearly along the bottom surface 14′ of cell 10′ or on the surface of each tab that faces toward the bottom surface. Thus, each tab 28 is adhered to the bottom surface of cell 10′ by one of beads 22′, in a manner similar to the adhesion of tabs 28 to the top surface of cell 10 by beads 22. Aside from their disposition between the tab and the bottom surface of cell 10′ rather than between the tab and the top surface of cell 10, adhesive beads 22′ generally are substantially similar or identical in their properties to adhesive beads 22. That is, beads 22′ are formed from an electrically conductive adhesive, are applied in a thin layer that is at least slightly narrower than the tab, and may extend along 60%-80% or more of the length of bottom surface 14′. Accordingly, tabs 28 may extend along at least this fraction of the length of the bottom surface of cell 10′, resulting in secure electrical contact and adhesion between the tabs and the bottom surface of the cell. In alternative embodiments, typically those using either a thicker substrate or a more conductive substrate material such as titanium, the conductivity of the substrate may be sufficient to require only a smaller region of contact, and perhaps even only a point of contact, between the bead and the bottom surface of the cell.

Note that in some embodiments, the bottom surface 14′ of cell 10′ may not include conductive strips to facilitate electrical contact between tabs 28 and the bottom of the cell. This may be the case, for example, when the substrate material forming the bottom surface of the cells is itself metallic, such as when the substrate is formed from flexible stainless steel. In alternative embodiments, when the substrate is constructed from a different and perhaps less conductive and/or less adhesive material, the bottom surface of each cell may include metallic or otherwise highly conductive and adhesive strips aligned with the tabs, in much the same manner that the top surface of cell 10 may include conductive strips 20 to facilitate good adhesion and conductivity between tabs 28 and top surface 12 of cell 10.

As FIGS. 7-9 depict, one or more conductive tabs 28′ also typically are adhered to top surface 12′ of cell 10′. As depicted in FIGS. 7-8, when cell 10′ is the trailing cell in the string, so that no additional cell is disposed adjacent to trailing edge 18′, each tab 28′ may extend toward and beyond the trailing edge of cell 10′, passing over a dielectric patch 24′ and leaving an exposed trailing tab portion 32 of any desired length available for connection to a circuit. For example, a 70 mm trailing tab portion has been found convenient for cells of dimensions 100 mm×210 mm. Alternatively, when an additional cell (not shown) is disposed beyond the trailing edge of cell 10′, tabs 28′ may be bent or deformed in a region close to the trailing edge of cell 10′, to make contact with the bottom surface of the next cell in the string in substantially the same manner that tabs 28 are bent or deformed to contact the bottom side of cell 10′. Typically, the tab disposed on the top surface of whichever cell is the trailing cell in the string may include a trailing tab portion for convenient connection to a circuit.

As FIG. 8 depicts, additional tabs 28″ also will typically be adhered to the bottom surface 14 of cell 10. To facilitate this, additional beads of adhesive may be disposed between the bottom surface and the tabs, in the same manner that beads 22′ are disposed between the bottom surface of cell 10′ and tabs 28. As in the case of bottom surface 14′ of cell 10′, when the substrate material of cell 10 is metallic or an otherwise good conductor, there may be no need for conductive strips on the bottom surface of cell 10, although in some embodiments, such strips may be disposed on the bottom surface to facilitate adhesion and/or conduction between the surface and the tabs. As depicted in FIGS. 7-8, when cell 10 is the leading cell in the string, so that no additional cell is disposed adjacent to leading edge 16, each tab 28″ adhered to the bottom of cell 10 may extend toward and beyond the leading edge of cell 10, leaving an exposed leading tab portion 34 available.

As in the case of trailing tab portions 32, leading tab portions 34 may have any convenient length for convenient connection to a circuit, such as 70 mm. When an additional cell (not shown) is disposed beyond the leading edge of cell 10, tabs 28″ attached to the bottom of cell 10 may be bent or deformed upward and over the leading edge of cell 10 to make contact with the top surface of the next cell in the string, in substantially the same manner that tabs 28 are bent or deformed to contact both the bottom surface of cell 10′ and the top surface of cell 10. In this way, any desired number of cells may be interconnected in electrical series, to form a string or module of any desired voltage or power output, with leading and trailing tab portions extending from the leading and trailing edges of the string to allow convenient connection of the string into an electrical circuit.

Tabs 28, 28′, and 28″, as well as any additional tabs that might be employed to construct a string of more than two PV cells, typically all will be formed from the same material and to the same specifications. The material chosen for the tabs preferably should be a good conductor, should be flexible enough to be deformed in a relatively small region between adjacent cells, and should be suitable for sustaining both secure adhesion to the cells and a reliable electrical connection between cells, even when exposed to environmental conditions. Copper, possibly thinly coated with a metallic alloy, has been found suitable to meet these needs.

To reduce thermally-induced stress at the interfaces between the tabs and the cells, the tab material may be chosen to have a thermal expansion coefficient (TEC) that is similar to the TEC of the substrate material of the cells. For example, if the substrate material is characterized by TEC₁ and the tabs are characterized by TEC₂, it may be desirable to choose materials such that TEC₂ differs from TEC₁ by less than 20% of the value of TEC₁, i.e., such that

$$abs [ \frac{{TEC}_{1} - {TEC}_{2}}{{TEC}_{1}} ] < 0.20 .$$

This may be possible even if the materials of the tabs and the substrate differ. For instance, the TEC of stainless steel is approximately 17.3×10⁻⁶ K⁻¹ at 20° C., and the TEC of copper is approximately 17.0×10⁻⁶ K⁻¹ at 20° C., a difference of only around 1.8%. Thus, stresses between the tabs and the substrate may be greatly reduced if, for example, the cell substrate is constructed primarily from stainless steel and the tabs are constructed primarily from copper. When stainless steel is used for the cell substrate, an appropriate material for the tabs, which minimizes thermal expansion stress between the tabs and the cells, has been found to be copper ribbon coated with a layer of cladding and then a thin layer of tin/silver alloy. The cladding is a low expansion alloy such as Invar A36 that is clad or bonded to the copper core to allow better matching of the thermal expansion coefficients of the ribbon and cell materials. Suitable ribbons for use as tab material are manufactured, for example, by Torpedo Specialty Wire, Inc. of Rocky Mount, N.C., and sold as Part No. 0.005×0.098 LE69 Sn/Ag.

The dielectric material used to provide a nonconductive barrier at the PV cell edges can take a number of alternative forms to patches 24 described above. The present teachings simply contemplate reducing electrical shorts with some form of dielectric material disposed both between the conductive tab and a trailing edge of one PV cell, and between the conductive tab and a leading edge of another, adjacent cell. Accordingly, these alternative forms of dielectric material can either replace patches 24, or be used together with patches 24 in some embodiments. As depicted in FIG. 10, for example, a dielectric material 24a can be applied directly to conductive tab 28 (as well as tabs 28′, etc.) in the region where tab 28 crosses trailing edge 18 of cell 10 and leading edge 16′ of cell 10′.

Dielectric material 24a depicted in FIG. 10 may be applied to the tabs as a liquid and cured, for example, by thermal or UV radiation prior to attaching the tabs to their respective PV cells, or it may take the form of single-sided or double-sided adhesive tape applied to the tabs. In the case of double-sided tape, the adhesive properties of the dielectric tape may provide the additional benefit of bonding each tab to its respective cell in the edge region. In the case of either single-sided or double-sided adhesive dielectric tape, the tape should have dimensions suitable to prevent undesirable electrical contact between the conductive tab and the cell edge. For instance, the tape may be wrapped partially around the tab, or it may encircle the tab entirely in the region where the tab crosses the cell edge.

As depicted in FIGS. 11-12, another alternative form of dielectric barrier between the conductive tabs and the PV cell edges is a dielectric adhesive tape (24b in FIG. 11, 24c in FIG. 12) applied to the cells in the edge regions where the tabs will cross the cells when attached. Again, this tape can be used either to replace patches 24 or in addition to patches 24, and may be either single-sided or double-sided, with double-sided tape providing the possible advantage of additional adhesion between the tabs and the cells. When tape is applied to the cells in this manner, the tape may extend beyond the cell edge slightly to ensure good insulation between the tab and the cell edge. The tape should also be wide enough to provide insulation across the entire width of a tab to be attached. For example, as depicted at 24c in FIG. 12, the tape may be applied in discrete pieces, each of which is slightly wider than a single conductive tab, or as depicted at 24b in FIG. 11, the tape may extend along the entire cell edge over which tabs will cross.

Dielectric tape used in the manner described above may be constructed from appropriate materials to withstand the rigors of a PV cell environment over a long period of time. For example, the tape should have strength and thickness sufficient to avoid being penetrated by sharp edges that may exist at the cut edge region of a cell, and must be able to tolerate the temperatures and electric currents likely to exist in the PV cell environment. The dielectric material also should be chemically compatible with other materials used in the PV module, should be UV stable, and ideally would be relatively transparent. Suitable materials may include, for instance, polyethylene terephthalate (PET) coated with acrylic or some other thermosetting adhesive, or a phenolic compound that is UV or thermally cured, among others.

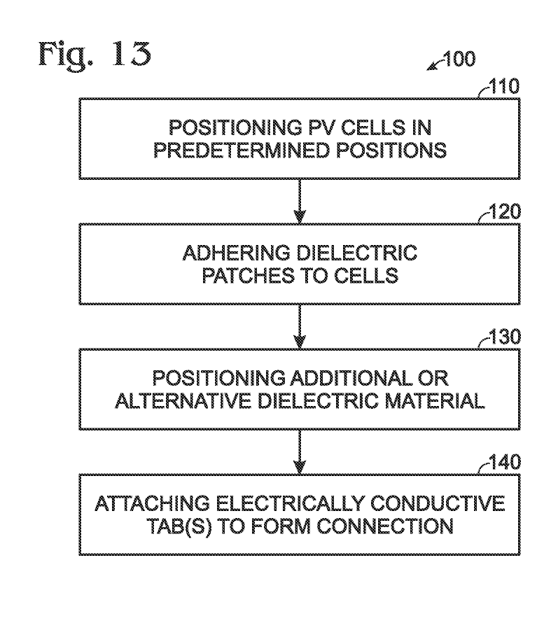

A number of methods of manufacturing strings and modules of PV cells are contemplated by the present teachings, and an exemplary method is depicted in FIG. 13 and generally indicated at 100. At step 110 of method 100, two or more PV cells are positioned in predetermined positions relative to each other. This may include positioning first and second PV cells, or it may include positioning additional cells at the same time, in embodiments where three or more cells are joined to form a string or module. At step 120, dielectric patches are adhered to the cells in a manner that has previously been described. For example, step 120 may include adhering a first dielectric patch to the top surface of the first cell and the trailing edge of the first cell, and adhering a second dielectric patch to the bottom surface of the second cell and the leading edge of the second cell. As has been discussed in detail above, the primary purpose of these patches is to avoid undesirable electrical shorting between opposite polarity sides of a given PV cell. However, it should be appreciated that step 120 may be omitted according to the present teachings if one or more alternative dielectric materials are used.

At step 130 of method 100, additional or alternative dielectric material is positioned, again to help avoid undesirable electrical contact between the top and bottom of a given cell. Step 130 may be performed either in addition to step 120 (and either before or after step 120), step 120 may be omitted and replaced by step 130, or step 130 may be omitted. In other words, the present teachings using any combination of dielectric patches and/or other dielectric material to help prevent electrical shorting at the edges of the PV cells. When step 130 is performed, the additional dielectric material is positioned to be disposed so that it will separate both the trailing edge of one cell and the leading edge of an adjacent cell from an electrically conducting tab that either has been or will be attached to the cells as described below. Accordingly, step 130 may include, for example, coating the tab with a dielectric such as a heat-curable or UV-curable dielectric liquid, or wrapping single-sided or double-sided dielectric tape around the tab in the region where it will cross the edges of the adjacent cells. Alternatively (or additionally), step 130 may include applying dielectric tape directly to the trailing and leading edges of the PV cells over at least the region where the conductive tab will cross those edges. Dielectric materials applied to the cells in steps 120 and/or 130 may be applied manually or automatically, such as robotically. This includes both dielectric patches and also tapes and liquid coatings.

At step 140, an electrically conducting tab is attached to the top surface of one cell and the bottom surface of an adjacent cell to form an electrical series connection between the two cells. As described previously, the tab may be attached to the cells with an electrically conductive adhesive, and a conducting strip may be used to facilitate the electrical connection between the tab and the top (radiation receiving) surface of a given PV cell. The tab will be positioned so that whatever dielectric material is used to help prevent undesirable electrical shorts at the cell edges, including dielectric patches, curable liquids, and tape, among others, is positioned between the tab and the edge regions of the cells crossed by the tab as it electrically joins adjacent cells. Finally, it should be appreciated that although the use of a single tab has been described in these teachings, multiple tabs may be used to connect adjacent PV cells, in which case any conducting strips, conductive adhesive, dielectric patches, and/or other materials may be applied periodically along the width of each cell. For example, three tabs are depicted forming an electrical connection between adjacent cells in FIGS. 1, 5, 7 and 8.

The disclosure set forth above may encompass multiple distinct inventions with independent utility. Although each of these inventions has been disclosed in its preferred form(s), the specific embodiments thereof as disclosed and illustrated herein are not to be considered in a limiting sense, because numerous variations are possible. The subject matter of the inventions includes all novel and nonobvious combinations and subcombinations of the various elements, features, functions, and/or properties disclosed herein. The following claims particularly point out certain combinations and subcombinations regarded as novel and nonobvious. Inventions embodied in other combinations and subcombinations of features, functions, elements, and/or properties may be claimed in applications claiming priority from this or a related application. Such claims, whether directed to a different invention or to the same invention, and whether broader, narrower, equal, or different in scope to the original claims, also are regarded as included within the subject matter of the inventions of the present disclosure.

We claim:

1. A thin film photovoltaic module, comprising:
first and second thin film photovoltaic cells, each cell having a length running from a leading edge to a trailing edge, a top surface, and a bottom surface;
an electrically conductive grid disposed on the top surface of each cell, each grid including a longitudinal conductive strip;
an electrically conductive tab attached, using electrically conductive adhesive (ECA), to the conductive strip of the first cell over most of the length of the first cell and attached to the bottom surface of the second cell to form an electrical series connection between the first and second cells, the conductive tab, ECA, conductive strip, and first cell defining a flexible, connected stack along most of the length of the first cell; and
dielectric material disposed between the conductive tab and a trailing edge of the first cell, and between the conductive tab and a leading edge of the second cell.

2. The module of claim 1, wherein the conductive tab is adhered to the conductive strip with a first continuous and substantially linear bead of electrically conductive adhesive, and wherein the conductive tab is adhered to the bottom surface of the second cell with a second continuous and substantially linear bead of electrically conductive adhesive.

3. The module of claim 2, wherein the first and second cells have a substantially similar length, and the second bead of electrically conductive adhesive and the conductive tab each extend across at least 60 percent of the length of the second cell.

4. The module of claim 1, wherein the dielectric material includes a first dielectric patch adhered to the top surface of the first cell and the trailing edge of the first cell, and a second dielectric patch adhered to the bottom surface of the second cell and the leading edge of the second cell.

5. The module of claim 1, wherein the dielectric material includes a first layer of dielectric adhesive tape covering the trailing edge of the first cell in a region where the conductive tab crosses the trailing edge, and a second layer of dielectric adhesive tape covering the leading edge of the second cell in a region where the conductive tab crosses the leading edge.

6. The module of claim 1, wherein the dielectric material is applied directly to the conductive tab in regions where the tab crosses the trailing edge of the first cell and the leading edge of the second cell.

7. The module of claim 6, wherein the dielectric material is applied to the conductive tab as a curable liquid.

8. The module of claim 6, wherein the dielectric material is adhesive dielectric tape encircling the tab.

9. A string of thin film photovoltaic cells, comprising:
first and second flexible thin film photovoltaic cells, each cell having a substrate, a top surface, and a bottom surface;
the top surface of the first cell having a collection grid including a conductive strip oriented substantially perpendicular to a trailing edge of the first cell;
a first dielectric tape patch attached to the top surface of the first cell and overlapping at least a portion of the trailing edge of the first cell;
a second dielectric tape patch attached to the bottom surface of the second cell and overlapping at least a portion of a leading edge of the second cell; and
a first electrically conductive tab adhered to the conductive strip on the top surface of the first cell by electrically conductive adhesive (ECA), passing over the first and second dielectric patches, and adhered to the bottom surface of the second cell by electrically conductive adhesive,
wherein the conductive tab has a thermal expansion coefficient which is substantially similar to the thermal expansion coefficients of the substrates of the cells;
and the conductive tab, ECA, conductive strip, and first cell define a flexible, connected stack along most of the length of the first cell.

10. The string of claim 9, wherein the trailing edge of the first cell and the leading edge of the second cell each have a thickness, wherein the first dielectric patch overlaps substantially the entire thickness of the trailing edge of the first cell, and wherein the second dielectric patch overlaps substantially the entire thickness of the leading edge of the second cell.

11. The string of claim 9, wherein the conductive strip is substantially linear and is configured to increase electrical conductivity between the first cell and the conductive tab.

12. The string of claim 9, further comprising a dielectric coating applied to the conductive tab and configured to overlap the trailing edge of the first cell and the leading edge of the second cell.

13. The string of claim 12, wherein the dielectric coating is applied to the conductive tab as a curable liquid.

14. The string of claim 12, wherein the dielectric coating is a layer of dielectric tape wrapped at least partially around the conductive tab.

15. The string of claim 9, further comprising:
a first portion of dielectric adhesive tape applied to the first cell and configured to electrically separate the conductive tab from the trailing edge of the first cell; and
a second portion of dielectric adhesive tape applied to the second cell and configured to electrically separate the conductive tab from the leading edge of the second cell.

16. A method of manufacturing a photovoltaic module, comprising:
positioning first and second photovoltaic cells in predetermined positions relative to each other;
attaching an electrically conducting tab to a top surface of the first cell and to a bottom surface of the second cell to form an electrical series connection between the first and second cells; and
positioning dielectric material between the tab and a trailing edge of the first cell and between the tab and a leading edge of second cell.

17. The method of claim 16, wherein positioning dielectric material includes:
adhering a first dielectric patch to the top surface of the first cell and the trailing edge of the first cell; and
adhering a second dielectric patch to the bottom surface of the second cell and the leading edge of the second cell.

18. The method of claim 16, wherein positioning dielectric material includes coating the tab with a curable dielectric liquid.

19. The method of claim 16, wherein positioning dielectric material includes adhering dielectric tape to the tab.

20. The method of claim 16, wherein positioning dielectric material includes applying dielectric adhesive tape to the trailing edge of the first cell and the leading edge of the second cell.
